(19) United States
(12) Patent Application Publication
(10) Pub. No.: US 2026/0222719 A1
(43) Pub. Date: Jul. 30, 2026

(54) DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Qiumei WEI, Beijing (CN); Yuju CHEN, Beijing (CN); Yingzi WANG, Beijing (CN)

(21) Appl. No.: 19/145,557

(22) PCT Filed: Jun. 12, 2024
(86) PCT No.: PCT/CN2024/098769

§ 371 Date: Jul. 3, 2025

(30) Foreign Application Priority Data
Jul. 27, 2023 (CN) 202310936983.9

(51) Int. Cl. H04R 1/02; G09G 3/3225; H04R 1/28; H04R 1/32; H04R 17/10; H10H 29/24; H10K 59/95

(52) U.S. Cl. CPC H04R 1/028; G09G 3/3225; H04R 1/025; H04R 1/2803; H04R 1/323; H04R 17/10; H04R 2499/15; H10H 29/24; H10K 59/95

(57) ABSTRACT

A display panel includes a base substrate having a first surface and a second surface arranged opposite each other. The display panel further includes a plurality of light-emitting units on the first surface of the base substrate, and a plurality of sound-generating units on the first surface of the base substrate and between adjacent light-emitting units. The sound-generating unit includes: a piezoelectric device on the first surface of the base substrate; a sound focusing structure arranged on the first surface of the base substrate and surrounding the piezoelectric device; and a back cavity arranged on the second surface of the base substrate and recessed towards the first surface. The back cavity is arranged corresponding to the piezoelectric device.

### CROSS-REFERENCE TO RELATED APPLICATIONS

This application is a national phase entry under 35 U.S.C. § 371 of International Application No. PCT/CN2024/098769, filed on Jun. 12, 2024, which claims priority to Chinese Patent Application No. 202310936983.9, filed to the China National Intellectual Property Administration on Jul. 27, 2023, and entitled “Display Panel and Display Device”, the entire contents of which are incorporated herein by reference.

### TECHNICAL FIELD

The present disclosure relates to the field of display technology, and in particular to a display panel and a display device.

### BACKGROUND

With the continuous development of display technology, the application scope of display devices is becoming more and more extensive, and accordingly people's requirements for display devices to integrate various functions are becoming higher and higher. Screen sound has become the mainstream. The principle of screen sound technology is to drive the screen and structure in front through an exciter, use the screen as a vibrating body, and generate sound waves through vibration to be transmitted to the human ear. However, existing screen sound technologies generally have problems such as insufficient sound directionality and poor timbre.

### SUMMARY

Embodiments of the present disclosure provide a display panel and a display device. The scheme is as follows.

A display panel provided by embodiments of the present disclosure includes a base substrate having a first surface and a second surface arranged opposite to each other. The display panel further includes: a plurality of light-emitting units arranged on the first surface of the base substrate, and a plurality of sound-generating units arranged on the first surface of the base substrate and between adjacent light-emitting units.

The sound-generating unit includes:
a piezoelectric device arranged on the first surface of the base substrate;
a sound focusing structure arranged on the first surface of the base substrate and surrounding the piezoelectric device; and
a back cavity arranged on the second surface of the base substrate and recessed toward the first surface, the back cavity being arranged corresponding to the piezoelectric device.

In a possible implementation, in the display panel provided by embodiments of the present disclosure, the depth of the back cavity is less than the thickness of the base substrate and greater than 80% of the thickness of the base substrate.

In a possible implementation, in the display panel provided by embodiments of the present disclosure, the sizes of the back cavities of the sound-generating units are the same. Alternatively, the sizes of the back cavities of some sound-generating units are different.

In a possible implementation, in the display panel provided by embodiments of the present disclosure, the base substrate is divided into a first supporting portion corresponding to the back cavity, a second supporting portion surrounding the first supporting portion, and at least two connecting portions arranged at intervals. The first supporting portion and the second supporting portion are connected through the at least two connecting portions. A through via penetrating the base substrate is provided between two adjacent connecting portions. The first supporting portion, the second supporting portion and the at least two connecting portions are an integrally formed structure.

In a possible implementation, in the display panel provided by embodiments of the present disclosure, the shape of the second supporting portion is complementary to the shape of the first supporting portion. The shape of the first supporting portion includes a circle, a square or a polygon.

In a possible implementation, in the display panel provided by embodiments of the present disclosure, the piezoelectric device includes a first electrode, a piezoelectric layer, and a second electrode stacked in sequence on a side of the first support portion away from the back cavity. The ratio of the thickness of the first support portion to the thickness of the piezoelectric layer is 1 to 10.

In a possible implementation, in the display panel provided by embodiments of the present disclosure, a pore penetrating the piezoelectric device and the first supporting portion is provided inside the sound-generating unit. A size of the pore is 0 to 9 μm.

In a possible implementation, in the display panel provided by embodiments of the present disclosure, the angle between the tangent line of the inner wall of the sound focusing structure and the base substrate is greater than 0° and less than or equal to 90°.

In a possible implementation, in the display panel provided by embodiments of the present disclosure, the cross-sectional shape of the inner wall of the sound focusing structure along the thickness direction of the base substrate includes a straight line, a parabola, a polyline or a sawtooth shape.

In a possible implementation, in the display panel provided by embodiments of the present disclosure, the thickness of the sound focusing structure is 10 μm to 100 μm, and the width of the sound focusing structure is 30 μm to 100 μm.

In a possible implementation, in the display panel provided by embodiments of the present disclosure, a gap is provided between the sound focusing structure and the piezoelectric device. The width of the gap is greater than or equal to 0 and less than or equal to half of the width of the piezoelectric device.

In a possible implementation, in the display panel provided by embodiments of the present disclosure, the plurality of light emitting units are arranged on one side of the base substrate in an array. A column of the sound-generating units is provided at least between two adjacent columns of the light emitting units.

In a possible implementation, in the display panel provided by embodiments of the present disclosure, a column of the sound-generating units is provided between every two adjacent columns of the light emitting units.

In a possible implementation, in the display panel provided by embodiments of the present disclosure, the plurality of light-emitting units include multiple rows and columns of the light-emitting units. One column of the light-emitting units at least in two adjacent columns of the light-emitting units is arranged at odd-numbered row positions, and the other column of the light-emitting units in the two adjacent columns is arranged at even-numbered row positions. The sound-generating units are arranged at intervals at even-numbered row positions of the one column of the light-emitting units, and/or the sound-generating units are arranged at intervals at odd-numbered row positions of the other column of the light-emitting units.

In a possible implementation, in the display panel provided by embodiments of the present disclosure, the first electrodes of the piezoelectric devices in the sound-generating units in the same column are electrically connected to a first driving voltage terminal through a first lead. The second electrodes of the piezoelectric devices in the sound-generating units in the same column are electrically connected to a second driving voltage terminal through a second lead.

In a possible implementation, in the display panel provided by embodiments of the present disclosure, the sizes of the piezoelectric layers in the piezoelectric devices are the same. Alternatively, the sizes of the piezoelectric layers in some piezoelectric devices are different.

In a possible implementation, in the display panel provided by embodiments of the present disclosure, each of the light-emitting units includes at least one light-emitting element. The light-emitting element includes a light-emitting diode chip or an organic light-emitting diode.

In a possible implementation, the display panel provided by embodiments of the present disclosure further includes a driving circuit located between the base substrate and the light-emitting unit. The light-emitting unit and the sound-generating unit share the driving circuit.

In a possible implementation, in the display panel provided by embodiments of the present disclosure, the thickness of the piezoelectric layer in the piezoelectric device is 1 μm to 10 μm.

In a possible implementation, in the display panel provided by embodiments of the present disclosure, the material of the piezoelectric layer in the piezoelectric device includes at least one of lead zirconate titanate, aluminum nitride, zinc oxide, barium titanate, lead titanate, potassium niobate, lithium niobate, lithium tantalate, or lanthanum gallium silicate.

Correspondingly, embodiments of the present disclosure further provide a display device, including the above-mentioned display panel provided by embodiments of the present disclosure.

### BRIEF DESCRIPTION OF DRAWINGS

FIG. 1 is a schematic diagram of a planar structure of a display panel provided by an embodiment of the present disclosure.

FIG. 2 is a schematic cross-sectional view along the AA′ direction in FIG. 1.

FIG. 3A to FIG. 3C are schematic diagrams showing back cavities with different sizes.

FIG. 4 is a schematic diagram of a partial planar structure of the base substrate 1 in FIG. 2.

FIG. 5A is a schematic diagram showing the relationship between the ratio of the thickness of the first support portion to the thickness of the piezoelectric layer and the sound pressure level (SPL).

FIG. 5B is a schematic diagram showing the relationship between the ratio of the thickness of the first support portion to the thickness of the piezoelectric layer and the sensitivity.

FIG. 6A to FIG. 6C are schematic diagrams showing pores penetrating the piezoelectric device and the first supporting portion being provided inside the sound-generating units with back cavities of different sizes.

FIG. 7 is a schematic cross-sectional view of a sound focusing structure.

FIG. 8A is another schematic cross-sectional view of a sound focusing structure.

FIG. 8B is another schematic cross-sectional view of the sound focusing structure.

FIG. 8C is another schematic cross-sectional view of the sound focusing structure.

FIG. 9A shows an arrangement of sound-generating units.

FIG. 9B shows another arrangement of sound-generating units.

FIG. 10A shows another arrangement of sound-generating units.

FIG. 10B shows another arrangement of sound-generating units.

FIG. 11 is a schematic diagram showing the calculation principle of the neutral axis of the piezoelectric layer (diaphragm) of the sound-generating unit (speaker).

FIG. 12A to FIG. 12D are schematic diagrams of the integration of diaphragm units of different sizes.

FIG. 13A shows a time domain signal.

FIG. 13B shows a frequency domain signal of FFT (Fast Fourier Transform).

### DETAILED DESCRIPTION

In order to make the purpose, technical solution and advantages of the embodiments of the present disclosure more clear, the technical solution of the embodiments of the present disclosure will be clearly and completely described below in conjunction with the drawings of embodiments of the present disclosure. Obviously, the described embodiments are only part of the embodiments of the present disclosure, rather than all the embodiments. Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The words “include” or “comprise” and the like used in the present disclosure mean that the elements or objects preceding the words include the elements or objects listed after the words and their equivalents, but do not exclude other elements or objects. The words “connect” or “connected” and the like are not limited to physical or mechanical connections, but may include electrical connections, whether direct or indirect. “Inside”, “outside”, “upper”, “lower”, etc. are only used to indicate relative position relationships. When the absolute position of the object being described changes, the relative position relationship may also change accordingly.

It should be noted that the size and shape of each figure in the accompanying drawings do not reflect the actual proportion, and the purpose is only to illustrate the contents of the present disclosure. And the same or similar reference numerals throughout represent the same or similar elements or elements having the same or similar functions.

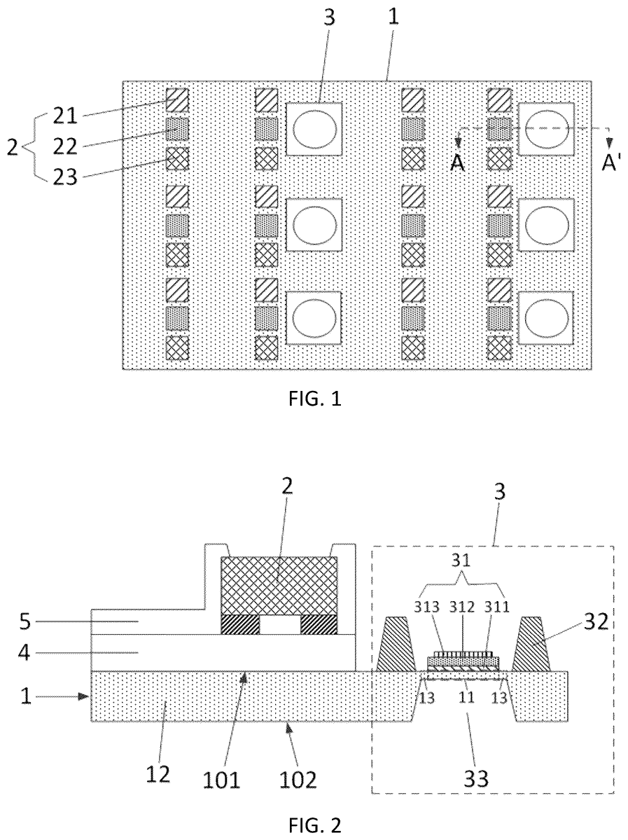

Embodiments of the present disclosure provide a display panel, as shown in FIG. 1 and FIG. 2. FIG. 1 is a schematic plan view of the display panel. FIG. 2 is a schematic cross-sectional view along the AA′ direction in FIG. 1. The display panel includes a base substrate 1. The base substrate 1 has a first surface 101 and a second surface 102 arranged opposite to each other. The display panel further includes: a plurality of light emitting units 2 arranged on the first surface 101 of the base substrate 1, and a plurality of sound-generating units 3 arranged on the first surface 101 of the base substrate 1 and between adjacent light emitting units 2.

The sound-generating unit 3 includes:
a piezoelectric device 31 arranged on the first surface 101 of the base substrate 1;
a sound focusing structure 32 arranged on the first surface 101 of the base substrate 1 and surrounding the piezoelectric device 31; and
a back cavity 33 arranged on the second surface 102 of the base substrate 1 and recessed toward the first surface 101, the back cavity 33 being arranged corresponding to the piezoelectric device 31.

In the display panel provided by the embodiments of the present disclosure, a plurality of sound-generating units are arranged between adjacent light-emitting units, so that the integration process of the display panel integrating the screen sound function is relatively simple. Further, the inverse piezoelectric effect of the piezoelectric device is used to generate deformation vibration to drive the air in the back cavity to vibrate and emit sound waves, thereby realizing screen sound. The sound focusing structure can have a sound focusing effect on the emitted sound, thereby improving the problems of poor timbre and insufficient sound directionality of traditional screen sound.

The sound-generating unit in embodiments of the present disclosure is equivalent to a speaker, that is, the speaker is integrated into the display panel to realize screen sound.

The base substrate may be a glass substrate, but is not limited thereto. Optionally, the glass substrate adopts high-temperature glass, and the thickness of the glass substrate may be 500 μm to 1000 μm.

In an implementation, in the display panel provided by embodiments of the present disclosure, as shown in FIG. 2, the depth of the back cavity 33 is less than the thickness of the base substrate 1 and greater than 80% of the thickness of the base substrate 1. The base substrate 1 includes a first supporting portion 11 corresponding to the back cavity 33. The first supporting portion 11 is formed after the back cavity 33 is prepared on the original base substrate 1, that is, the thickness of the first supporting portion 11 is less than 20% of the thickness of the base substrate 1. In this way, when the piezoelectric device 31 generates deformation vibration under the inverse piezoelectric effect, the first supporting portion 11 can be drove to vibrate, thereby driving the air in the back cavity 33 to vibrate and emit sound waves. However, if the depth of the back cavity 33 is less than 80% of the thickness of the base substrate 1, the thickness of the first support portion 11 is greater than 20% of the thickness of the base substrate 1. That is, the thickness of the first support portion 11 too thick, resulting in a poor vibration effect, which is not conducive to the screen sound.

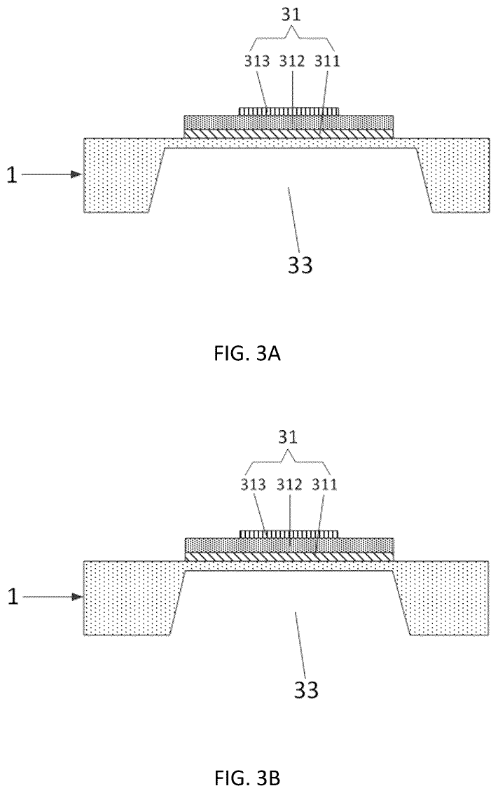

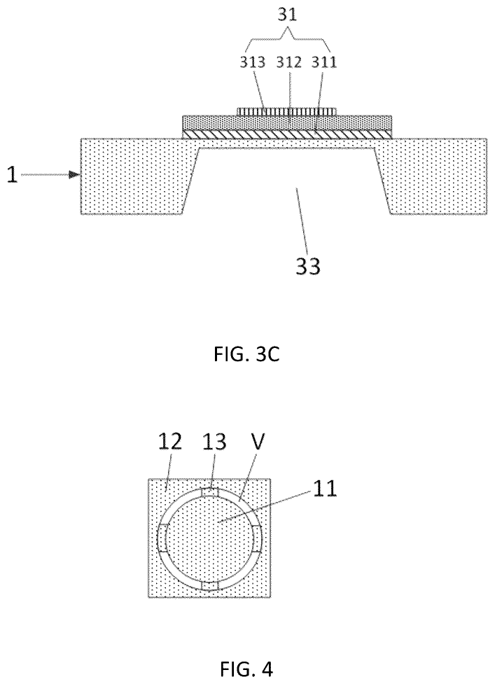

In an implementation, in the display panel provided by embodiments of the present disclosure, as shown in FIG. 1 and FIG. 2, the sizes of the back cavities 33 of the sound-generating unit 3 can be the same, so that the process for preparing the back cavity 33 can be unified and the process complexity can be reduced. Alternatively, the sizes of the back cavities 33 of the sound-generating units 3 shown in FIG. 1 may not be the same. For example, the sizes of the back cavities 33 of some sound-generating units 3 are larger. As shown in FIG. 3A, for example, the size of the back cavity 33 is larger than the size of the piezoelectric device 31. The sizes of the back cavities 33 of some sound-generating units 3 are mid-sized. As shown in FIG. 3B, for example, the size of the back cavity 33 is approximately equal to the size of the piezoelectric device 31. The sizes of the back cavities 33 of some sound-generating units 3 are smaller. As shown in FIG. 3C, for example, the size of the back cavity 33 is smaller than the size of the piezoelectric device 31. The size (e.g., volume) of the back cavity 33 can be adjusted as much as possible according to the installation position, and can be prepared by glass through-hole technology or laser-induced etching. Increasing the volume of the back cavity 33 can enhance the low-frequency effect, while reducing the volume of the back cavity 33 can enhance the high-frequency effect, thereby making the timbre richer. Therefore, those skilled in the art may design the sizes of the back cavities 33 according to actual needs, and the present disclosure does not limit this.

In an implementation, the display panel provided by embodiments of the present disclosure is as shown in FIG. 2 and FIG. 4. FIG. 4 is a schematic diagram of the local planar structure of the base substrate 1 in FIG. 2. The base substrate 1 includes a first supporting portion 11 corresponding to the back cavity 33 and a second supporting portion 12 surrounding the first supporting portion 11. The first supporting portion 11 and the second supporting portion 12 are connected by at least two connecting portions 13 arranged at intervals. A through via V penetrating the base substrate 1 is provided between two adjacent connecting portions 13. The first supporting portion 11, the second supporting portion 12 and the connecting portions 13 are an integrally formed structure. The first support portion 11 mainly supports the piezoelectric device 31. The first support portion 11 and the surrounding second support portion 12 are partially connected through the connecting portions 13, which is beneficial to increasing the amplitude of the piezoelectric device 31 during vibration, thereby improving the sound pressure level and sensitivity of the speaker.

Optionally, in the display panel provided by embodiments of the present disclosure, as shown in FIGS. 2 and 4, the shape of the second support portion 12 is complementary to the shape of the first support portion 11. For example, the shape of the first support portion 11 is circular, the inner annular surface of the second support portion 12 is also circular, and the diameter of the first support portion 11 can be 50 μm to 500 μm. Alternatively, the shape of the first support portion 11 can also be square, then the inner annular surface of the second support portion 12 is also square; the shape of the first support portion 11 can also be polygonal, then the inner annular surface of the second support portion 12 is also polygonal; and so on.

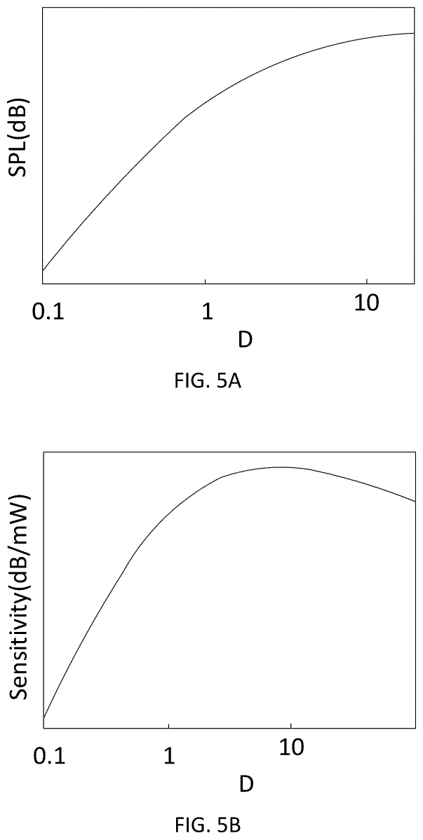

In an implementation, in the display panel provided by embodiments of the present disclosure, as shown in FIG. 2, the piezoelectric device 31 includes a first electrode 311, a piezoelectric layer 312, and a second electrode 313 which are sequentially stacked on the side of the first support portion 11 away from the back cavity 33. Different ratios of the thickness of the first support portion 11 to the thickness of the piezoelectric layer 312 affects the sound pressure level (SPL) and sensitivity (Sensitivity) of the speaker, as shown in FIGS. 5A and 5B. FIG. 5A is a schematic diagram showing the relationship between the ratio D of the thickness of the first support portion 11 to the thickness of the piezoelectric layer 312 and the sound pressure level (SPL). FIG. 5B is a schematic diagram showing the relationship between the ratio D of the thickness of the first support portion 11 to the thickness of the piezoelectric layer 312 and the sensitivity. It can be seen that when the ratio of the thickness of the first support portion 11 to the thickness of the piezoelectric layer 312 is between 1 and 10, the sound effect of the sound-generating unit 3 is better. Therefore, in embodiments of the present disclosure, the ratio of the thickness of the first support portion 11 to the thickness of the piezoelectric layer 312 is set to 1 to 10.

In an implementation, in the display panel provided by embodiments of the present disclosure, as shown in FIG. 2, the first electrode 311 is generally grounded, and the second electrode 313 is generally connected to a driving voltage terminal. By loading a ground voltage on the first electrode 311 and loading a high-frequency AC voltage on the second electrode 313, an alternating electric field is formed between the first electrode 311 and the second electrode 313. The piezoelectric layer 312 vibrates under the action of the alternating electric field, and drives the first support portion 11 to vibrate, thereby driving the air in the back cavity 33 to vibrate and emit sound waves.

In an implementation, in the display panel provided by embodiments of the present disclosure, as shown in FIG. 2, the thickness of the piezoelectric layer 312 may be 1 μm to 10 μm. For example, the thickness of the piezoelectric layer 312 is 1 μm, 2 μm, 3 μm, 4 μm, 5 μm, 6 μm, 7 μm, 8 μm, 9 μm, or 10 μm.

In an implementation, the material of the piezoelectric layer can be lead zirconate titanate (Pb(Zr,Ti)O₃, PZT), or at least one of aluminum nitride (AlN), zinc oxide (ZnO), barium titanate (BaTiO₃), lead titanate (PbTiO₃), potassium niobate (KNbO₃), lithium niobate (LiNbO₃), lithium tantalate (LiTaO₃), or lanthanum gallium silicate (La₃Ga₅SiO₁₄). The material for preparing the piezoelectric layer can be selected according to actual needs of technicians in this field, and no limitation is made here. For example, when PZT is used to prepare the piezoelectric layer, since PZT has a high piezoelectric coefficient, the piezoelectric characteristics of the corresponding piezoelectric sensor are guaranteed, and the corresponding piezoelectric sensor can be applied to the haptic feedback device. In addition, PZT has high light transmittance, when integrated into a display device, it does not affect the display quality of the display device.

Optionally, the piezoelectric layer may be prepared by sputtering or a sol-gel method, but is not limited thereto.

In an implementation process, the first electrode and the second electrode can be made of indium tin oxide (ITO), or indium zinc oxide (IZO), and can also be made of one of titanium-gold (Ti—Au) alloy, titanium-aluminum-titanium (Ti—Al—Ti) alloy, or titanium-molybdenum (Ti—Mo) alloy. In addition, the first electrode and the second electrode can also be made of one of platinum (Pt), titanium (Ti), gold (Au), silver (Ag), molybdenum (Mo), copper (Cu), tungsten (W), or chromium (Cr). Those skilled in the art can make the electrodes according to actual application needs, and there is no limitation here.

Optionally, the first electrode and the second electrode may be prepared by sputtering or electron evaporation, but is not limited thereto.

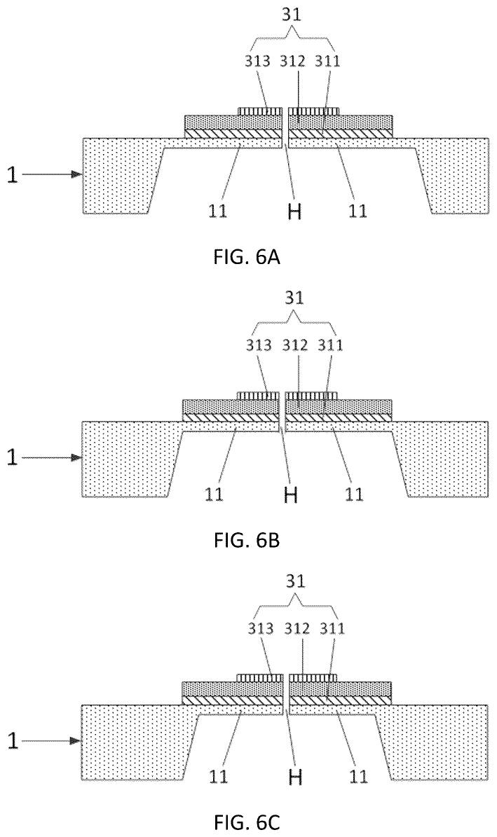

In an implementation, the display panel provided by embodiments of the present disclosure is as shown in FIGS. 6A to 6C. FIG. 6A is a schematic diagram showing a deformation of FIG. 3A. FIG. 6B is a schematic diagram showing a deformation of FIG. 3B. FIG. 6C is a schematic diagram showing a deformation of FIG. 3C. A pore H penetrating the piezoelectric device 31 and the first support portion 11 is provided inside the sound-generating unit 3. The size of the pore H can be 0 μm to 9 μm. The setting of the pore H can enhance the low-frequency response. Optionally, the shape of the orthographic projection of the pore H on the base substrate 1 may be a circle, and the diameter of the circle is 0-9 μm.

In an implementation, in the display panel provided by embodiments of the present disclosure, as shown in FIG. 7, the angle θ between the tangent line L of the inner wall of the sound focusing structure 32 and the base substrate 1 is greater than 0° and less than or equal to 90°, so as to improve the sound focusing effect of the sound focusing structure 32.

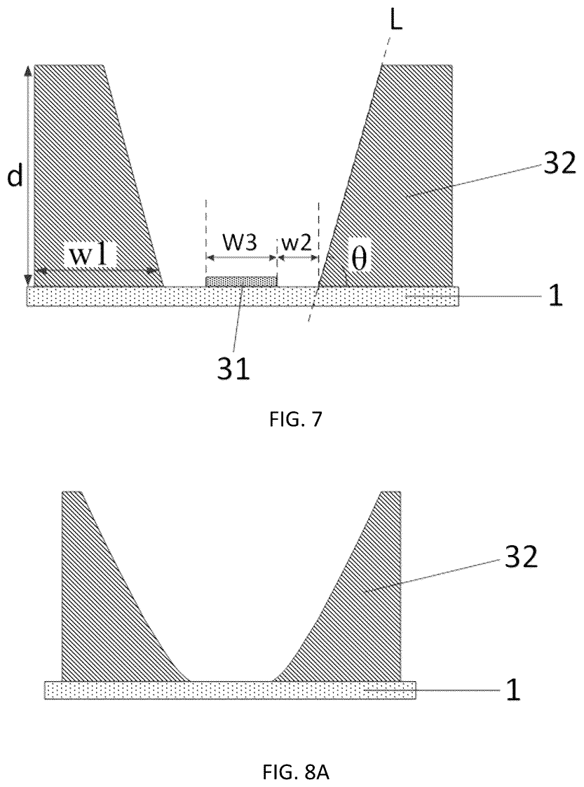

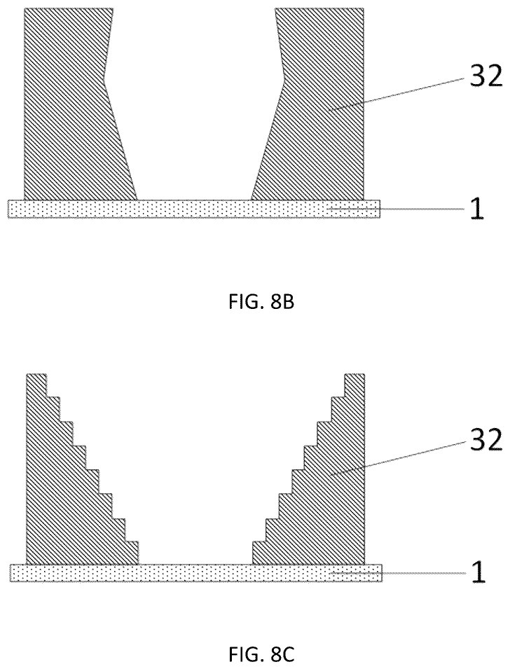

In an implementation, in the display panel provided by embodiments of the present disclosure, as shown in FIG. 7, the cross-sectional shape of the inner wall of the sound focusing structure 32 along the thickness direction of the base substrate 1 is a straight line, but is not limited to this. For example, as shown in FIG. 8A, the cross-sectional shape of the inner wall of the sound focusing structure 32 along the thickness direction of the base substrate 1 may be a parabola. As shown in FIG. 8B, the cross-sectional shape of the inner wall of the sound focusing structure 32 along the thickness direction of the base substrate 1 may be a polyline. As shown in FIG. 8C, the cross-sectional shape of the inner wall of the sound focusing structure 32 along the thickness direction of the base substrate 1 may be a sawtooth shape. The cross-sectional shape of the inner wall of the sound focusing structure 32 is not limited to this.

In an implementation, in order to enhance the sound focusing effect of the sound focusing structure, in the display panel provided by embodiments of the present disclosure, as shown in FIGS. 2 and 7, the thickness d of the sound focusing structure 32 can be 10 μm~100 μm, and the width w1 of the sound focusing structure 32 can be 30 μm~100 μm.

In an implementation, in the display panel provided by embodiments of the present disclosure, as shown in FIG. 2 and FIG. 7, there is a gap between the sound focusing structure 32 and the piezoelectric device 31. The width w2 of the gap is greater than or equal to 0 and less than or equal to half of the width w3 of the piezoelectric device 31.

Optionally, the sound focusing structure may be made of photoresist or sound-absorbing material. For example, the sound focusing structure may be formed by photolithography when the piezoelectric device is prepared.

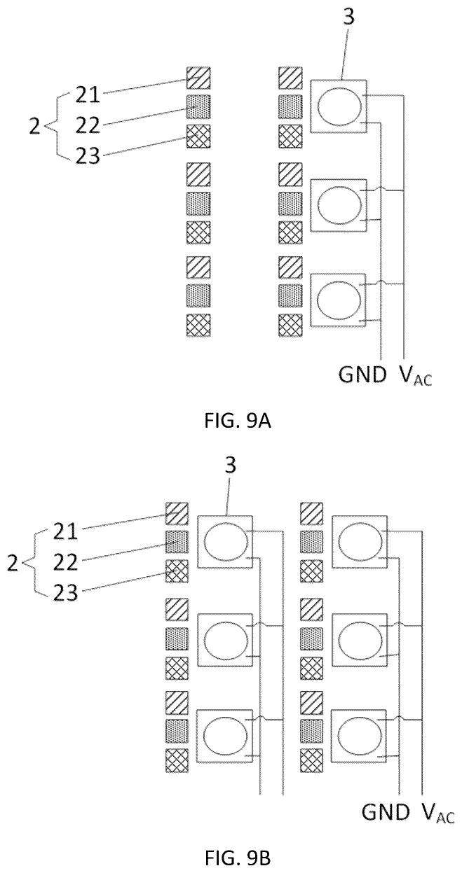

In an implementation, in the display panel provided by embodiments of the present disclosure, as shown in FIG. 9A and FIG. 9B, a plurality of light-emitting units 2 are arranged on one side of the base substrate 1 in an array. A column of sound-generating units 3 is provided at least between two adjacent columns of light-emitting units 2. For example, as shown in FIG. 9A, one column of sound-generating units 3 is arranged on one side of only one column of the light-emitting units 2 in two adjacent columns of light-emitting units 2. The structure shown in FIG. 9A is a single-column display and a single-column display and sound. As shown in FIG. 1 and FIG. 9B, a column of sound-generating units 3 is arranged between every two adjacent columns of light-emitting units 2. FIG. 1 and FIG. 9B show all columns integrating display and sound.

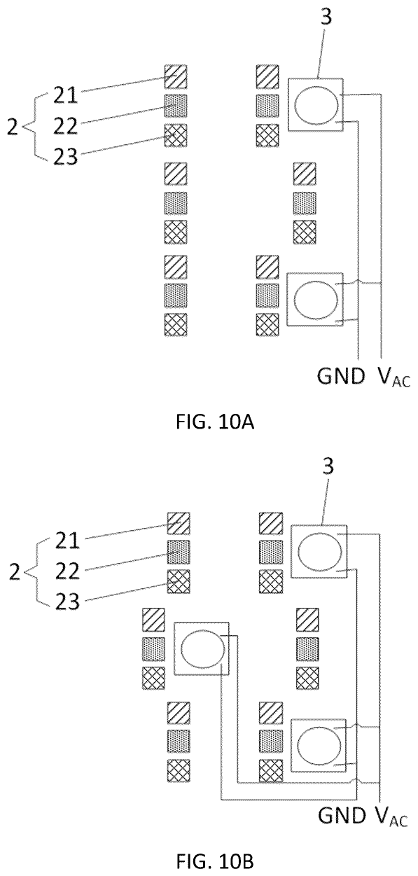

In an implementation, in the display panel provided by embodiments of the present disclosure, as shown in FIGS. 10A and 10B, the plurality of light-emitting units 2 include multiple rows and columns of light-emitting units 2 (the present disclosure only shows some rows and some columns). One column of the light-emitting units 2 at least in two adjacent columns of light-emitting units 2 is arranged at odd-numbered row positions, and the other column of light-emitting units 2 in the two adjacent columns of light-emitting units 2 is arranged at even-numbered row positions. The sound-generating units 3 are arranged at intervals at even-numbered row positions of the one column of the light-emitting units 2, and/or the sound-generating units 3 are arranged at intervals at odd-numbered row positions of the other column of the light-emitting units 2. In this way, the arrangement of the sound-generating units 3 in FIG. 10A and FIG. 10B is similar to a chessboard arrangement.

In an implementation, for driving the sound-generating units provided by the embodiments of the present disclosure, there are various driving methods, exemplarily including region-divided driving and full-region driving. For example, in the display panel provided by the embodiments of the present disclosure, as shown in FIGS. 9A, 9B and 10A, the first electrodes 311 of piezoelectric devices 31 in the same column of sound-generating units 3 are electrically connected to the first driving voltage terminal (ground terminal GND) through the first lead. The second electrodes 313 of piezoelectric devices 31 in the same column of sound-generating units 3 are electrically connected to the second driving voltage terminal (AC voltage terminal V_{AC}) through the second lead. Thus, FIG. 9A, FIG. 9B and FIG. 10A can adopt column driving (region-divided driving), that is, driving the sound-generating unit 3 in different regions, thereby realizing sound in different regions of the screen.

As shown in FIG. 10B, the first electrodes 311 of piezoelectric devices 31 in all sound-generating units 3 are electrically connected to the first driving voltage terminal (ground terminal GND) through the first lead. The second electrodes 313 of piezoelectric devices 31 in all sound-generating units 3 are electrically connected to the second driving voltage terminal (AC voltage terminal V_{AC}) through the second lead. In this way, FIG. 10B uses full-region driving to achieve overall screen sound.

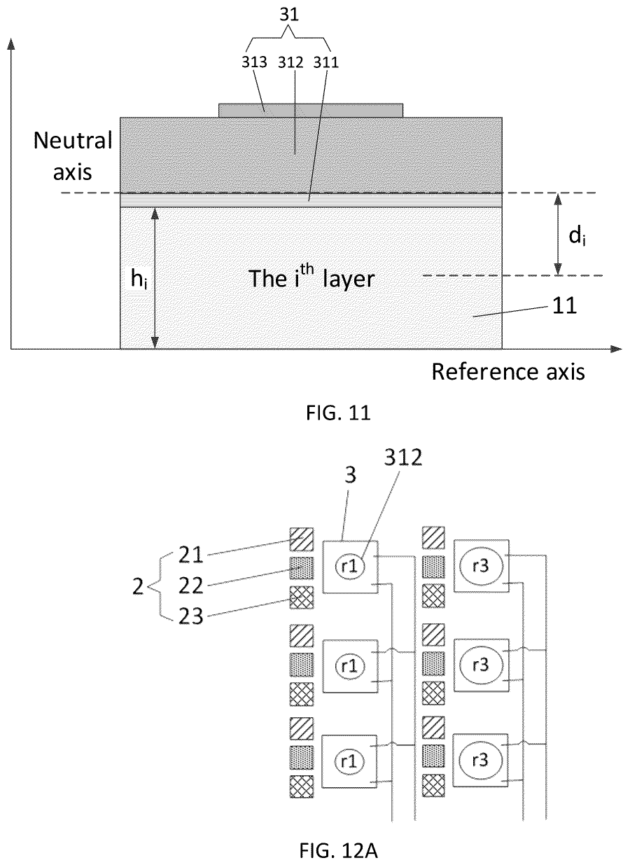

In an implementation, in the display panel provided by embodiments of the present disclosure, as shown in FIG. 2, the calculation principle of the neutral axis of the piezoelectric layer 312 (diaphragm) of the sound-generating unit 3 (speaker) is shown in FIG. 11. The natural frequency resonance characteristic of the diaphragm of the speaker is as in following formula (1):

$${f}_{0} = \frac{1}{2 π} \cdot \frac{3 . {2}^{2}}{{a}^{2}} \sqrt{\frac{D}{ρ}} \qquad ( 1 )$$

f₀ is the natural frequency of the base substrate. a is the radius of the diaphragm. D is the equivalent bending stiffness. ρ is the average area density.

$$D = {\sum }_{i} ( \frac{{E}_{i}}{1 - {v}_{i}^{2}} ) ( \frac{{h}_{i}^{3}}{12} + {d}_{i}^{2} {h}_{i} ) \qquad ( 2 )$$

$$ρ = {\sum }_{i} {ρ}_{i} {h}_{i} \qquad ( 3 )$$

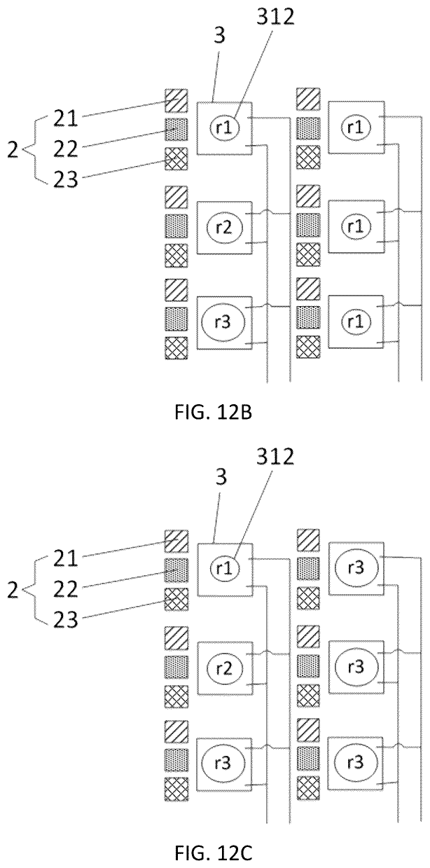

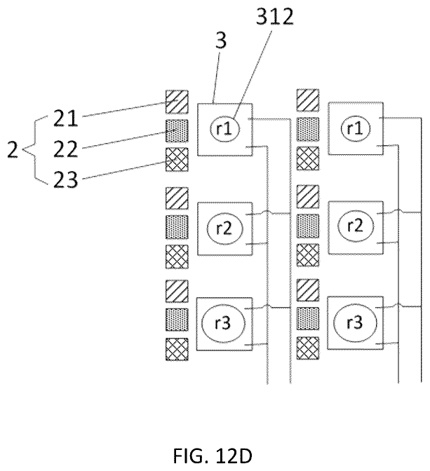

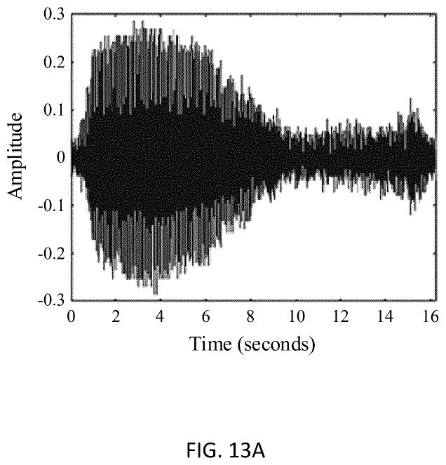

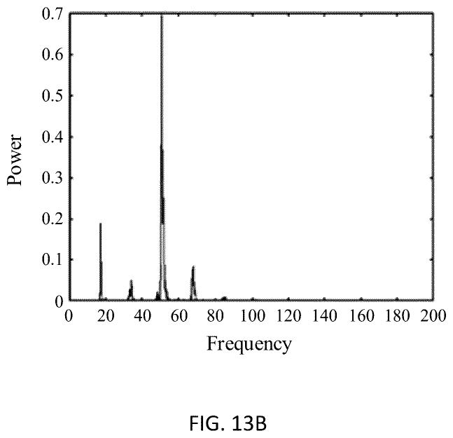

Eᵢ, vᵢ, hᵢ and ρᵢ are Young's modulus, Poisson's ratio, thickness and volume density of the i^{th} layer (first supporting part), respectively. dᵢ is the distance from the neutral axis to the mid plane of the i^{th} layer (the first support portion 11). It can be seen that adjusting the radius of the diaphragm can change the resonance frequency and frequency response characteristics of the diaphragm of the speaker. Therefore, the sound-generating unit 3 in the present disclosure can be configured to integrate diaphragm units of different sizes as shown in FIGS. 12A-12D to achieve multi-frequency driving. In FIGS. 12A-12D, r1, r2, and r3 represent diaphragms of different radii, r1<r2<r3, and all of them can be substituted into the above formula to achieve different frequency response characteristics. As shown in FIGS. 13A and 13B, FIG. 13A shows a time domain signal, and FIG. 13B shows a frequency domain signal of FFT (Fast Fourier Transform).

In an implementation, in the display panel provided by the embodiments of the present disclosure, as shown in FIG. 1, FIG. 9A, FIG. 9B and FIG. 10A, the size (for example, the radius is r3) of the piezoelectric layer 312 (diaphragm) in each piezoelectric device 31 may be the same.

In an implementation, controlling the arrangement of multiple sound-generating units in the array-distributed light-emitting units and the driving method of the sound-generating units can achieve better quality and more diverse sound effects, thereby effectively solving the problem of limited sound and quality in the existing technology integrating display and sound. For example, in the display panel provided by the embodiments of the present disclosure, as shown in FIGS. 12A-12D, the sizes of the piezoelectric layers 312 (diaphragms) in the piezoelectric devices 31 are not exactly the same. Optionally, as shown in FIG. 12A, in two adjacent columns of light-emitting units 2, the radii of the piezoelectric layers 312 (diaphragms) in a column of sound-generating units 3 on one side of one column of light-emitting units 2 may be the same, for example, each is r1. The radii of the piezoelectric layers 312 (diaphragms) in a column of sound-generating units 3 on one side of the other column of light-emitting units 2 may be the same, for example, each is r3. Optionally, as shown in FIG. 12B, in two adjacent columns of light-emitting units 2, the radii of the piezoelectric layers 312 (diaphragms) in a column of sound-generating units 3 on one side of one column of light-emitting units 2 may be different, for example, arranged in sequence as repeating units of r1, r2, and r3. The radii of the piezoelectric layers 312 (diaphragms) in a column of sound-generating units 3 on one side of the other column of light-emitting units 2 may be the same, for example, each is r1. Optionally, as shown in FIG. 12C, in two adjacent columns of light-emitting units 2, the radii of the piezoelectric layers 312 (diaphragms) in a column of sound-generating units 3 on one side of one column of light-emitting units 2 may be different, for example, arranged in sequence as repeating units of r1, r2, and r3. The radii of the piezoelectric layers 312 (diaphragms) in a column of sound-generating units 3 on one side of the other column of light-emitting units 2 may be the same, for example, each is r3. Optionally, as shown in FIG. 12D, the radii of the piezoelectric layers 312 (diaphragms) in a column of sound-generating units 3 on one side of each column of light-emitting units 2 are arranged in sequence as repeating units of r1, r2, and r3. Of course, the arrangement of the piezoelectric devices 31 with piezoelectric layers 312 (diaphragms) of different sizes is not limited to the above-mentioned arrangements listed in the present disclosure and can be designed according to needs.

In an implementation, the display panel provided by the embodiments of the present disclosure, as shown in FIG. 2, also includes a driving circuit 4 located between the base substrate 1 and the light-emitting unit 2. The light-emitting unit 2 and the sound-generating unit 3 can share the driving circuit 4, that is, the driving circuit 4 controls the display and the sound. For example, the driving circuit 4 is a TFT array layer. The TFT may be produced by LTPS process. Before forming the light-emitting unit 2 and the sound-generating unit 3 on the base substrate 1, the driving circuit 4 is formed on the base substrate 1. The driving circuit 4 is configured to drive the corresponding light-emitting unit 2 to emit light and drive the corresponding sound-generating unit 3 to make a sound.

In an implementation, in the display panel provided by the embodiments of the present disclosure, as shown in FIGS. 1, 9A, 9B, 10A, 10B, and 12A-12D, each light-emitting unit 2 includes at least one light-emitting element (taking three as an example, 21, 22 and 23 respectively). Optionally, the light-emitting element (21, 22 and 23) includes a light-emitting diode (LED) chip. An LED chip array can be formed on the driving circuit 4 by transfer printing. There is a gap between adjacent LED chips, and the sound-generating unit 3 is formed in the gap.

For example, as shown in FIG. 2, after the driving circuit 4 is formed, a bump pad can be used to electrically connect the LED chip. The bump pad is formed by Au—Sn or Au—In bonding. The LED may be a conventional micro-LED chip (micro-LED) flip chip structure. Materials such as SiNx may be used as the insulating passivation layer 5.

Optionally, the light emitting elements (21, 22 and 23) may include organic light emitting diodes (OLEDs). The OLEDs may be directly fabricated on the driving circuit 4. After the driving circuit 4 is formed, a plurality of light emitting elements (21, 22 and 23) are distributed in an array on the driving circuit 4. There is a gap of a certain width between adjacent light emitting elements (21, 22 and 23), and the sound-generating unit 3 is formed in the gap.

Optionally, the light emitting color of the light emitting element 21 is red, the light emitting color of the light emitting element 22 is green, and the light emitting color of the light emitting element 23 is blue.

Based on the same inventive concept, embodiments of the present disclosure further provide a display device, including the above-mentioned display panel provided by embodiments of the present disclosure. Since the principle of solving the problem of the display device is similar to that of the aforementioned display panel, the implementation of the display device can refer to the implementation of the aforementioned display panel, and the repeated parts will not be repeated. The display device may be any product or component with display or touch function, such as a mobile phone, a tablet computer, a television, a monitor, a notebook computer, a digital photo frame, a navigator, etc.

In an implementation, the display device provided by the embodiments of the present disclosure may also include other film layers well known to those skilled in the art, which will not be described in detail here.

The embodiments of the present disclosure provide a display panel and a display device. In the display panel provided by the embodiments of the present disclosure, a plurality of sound-generating units are arranged between adjacent light-emitting units, so that the integration process of the display panel integrating the screen sound function is relatively simple. Further, the inverse piezoelectric effect of the piezoelectric device is used to generate deformation vibration to drive the air in the back cavity to vibrate and emit sound waves, thereby realizing screen sound. The sound focusing structure can have a sound focusing effect on the emitted sound, thereby improving the problems of poor timbre and insufficient sound directivity of traditional screen sound.

Although preferred embodiments of the present disclosure have been described, additional changes and modifications may be made to these embodiments once those skilled in the art are aware of the basic inventive concepts. Therefore, it is intended that the appended claims be interpreted as including the preferred embodiment as well as all changes and modifications that fall within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalent technologies, the present disclosure is also intended to include these modifications and variations.

1.-21. (canceled)

22. A display panel, comprising:
a base substrate having a first surface and a second surface arranged opposite to each other;
a plurality of light-emitting units on the first surface of the base substrate; and
a plurality of sound-generating units on the first surface of the base substrate and between adjacent light-emitting units;
wherein the sound-generating unit comprises:
a piezoelectric device on the first surface of the substrate;
a sound focusing structure arranged on the first surface of the substrate and surrounding the piezoelectric device; and
a back cavity arranged on the second surface of the base substrate and recessed toward the first surface, the back cavity being arranged corresponding to the piezoelectric device.

23. The display panel according to claim 22, wherein a depth of the back cavity is less than a thickness of the base substrate and greater than 80% of the thickness of the base substrate.

24. The display panel according to claim 23, wherein:
sizes of back cavities of the plurality of sound-generating units are the same, or
sizes of back cavities of some sound-generating units among the plurality of sound-generating units are different.

25. The display panel according to claim 22, wherein the base substrate comprises:
a first supporting portion corresponding to the back cavity;
a second supporting portion surrounding the first supporting portion; and
at least two connecting portions arranged at intervals;
wherein the first supporting portion and the second supporting portion are connected through the at least two connecting portions, a through via penetrating the base substrate is provided between two adjacent connecting portions, and the first supporting portion, the second supporting portion and the at least two connecting portions are an integrally formed structure.

26. The display panel according to claim 25, wherein a shape of the second supporting portion is complementary to a shape of the first supporting portion, and the shape of the first supporting portion comprises a circle, a square or a polygon.

27. The display panel according to claim 25, wherein the piezoelectric device comprises a first electrode, a piezoelectric layer, and a second electrode stacked in sequence on a side of the first support portion away from the back cavity, and a ratio of a thickness of the first support portion to a thickness of the piezoelectric layer is 1 to 10.

28. The display panel according to claim 25, wherein a pore penetrating the piezoelectric device and the first supporting portion is provided inside the sound-generating unit, and a size of the pore is 0 to 9 μm.

29. The display panel according to claim 22, wherein an angle between a tangent line of an inner wall of the sound focusing structure and the base substrate is greater than 0° and less than or equal to 90°.

30. The display panel according to claim 29, wherein a cross-sectional shape of the inner wall of the sound focusing structure along a thickness direction of the base substrate comprises a straight line, a parabola, a polyline or a sawtooth shape.

31. The display panel according to claim 22, wherein a thickness of the sound focusing structure is 10 μm to 100 μm, and a width of the sound focusing structure is 30 μm to 100 μm.

32. The display panel according to claim 22, wherein a gap is provided between the sound focusing structure and the piezoelectric device, and a width of the gap is greater than or equal to 0 and less than or equal to half of a width of the piezoelectric device.

33. The display panel according to claim 22, wherein the plurality of light-emitting units are arranged on the first surface of the base substrate in an array, and a column of the sound-generating units is provided at least between two adjacent columns of the light-emitting units.

34. The display panel according to claim 33, wherein a column of the sound-generating units is provided between every two adjacent columns of the light-emitting units.

35. The display panel according to claim 22, wherein the plurality of light-emitting units comprise:
multiple rows and columns of the light-emitting units;
wherein one column of the light-emitting units at least in two adjacent columns of the light-emitting units is arranged at odd-numbered row positions, and the other column of the light-emitting units in the two adjacent columns of the light-emitting units is arranged at even-numbered row positions;
the sound-generating units are arranged at intervals at even-numbered row positions of the one column of the light-emitting units, and/or the sound-generating units are arranged at intervals at odd-numbered row positions of the other column of the light-emitting units.

36. The display panel according to claim 33, wherein first electrodes of the piezoelectric devices in the same column of the sound-generating units are electrically connected to a first driving voltage terminal through a first lead, and second electrodes of the piezoelectric devices in the same column of the sound-generating units are electrically connected to a second driving voltage terminal through a second lead.

37. The display panel according to claim 33, wherein sizes of piezoelectric layers in the piezoelectric devices are the same, or sizes of piezoelectric layers in some of the piezoelectric devices are different.

38. The display panel according to claim 22, wherein each of the plurality of light-emitting units comprises at least one light-emitting element, and the light-emitting element comprises a light-emitting diode chip or an organic light-emitting diode.

39. The display panel according to claim 22, further comprising:
a driving circuit between the base substrate and the light-emitting unit;
wherein the light-emitting unit and the sound-generating unit share the driving circuit.

40. The display panel according to claim 22, wherein a thickness of a piezoelectric layer in the piezoelectric device is 1 μm to 10 μm;
a material of a piezoelectric layer in the piezoelectric device comprises at least one of lead zirconate titanate, aluminum nitride, zinc oxide, barium titanate, lead titanate, potassium niobate, lithium niobate, lithium tantalate, or lanthanum gallium silicate.

41. A display device, comprising the display panel according to claim 22.
